(19) United States
(12) Patent Application Publication
(10) Pub. No.: US 2018/0287605 A1
(43) Pub. Date: Oct. 4, 2018

(54) CAPACITIVE SENSOR SYSTEM COMPRISING A SENSOR PORTION CONSISTING OF A SYNTHETIC CONSTRUCTION MATERIAL, METHOD FOR THE PRODUCTION OF SAID SYSTEM AND USE OF SAME

(71) Applicant: KENNWERT RD GMBH, Berlin (DE)

(72) Inventors: Thorsten KLOOSTER, Berlin (DE); Jan IWANOWICZ, Vellmar (DE); Jan JURASCHEK, Kassel (DE)

(73) Assignee: KENNWERT RD GMBH, Berlin (DE)

(21) Appl. No.: 15/761,021

(22) PCT Filed: Sep. 16, 2016
(86) PCT No.: PCT/EP2016/071943

§ 371 Date: Mar. 16, 2018

(30) Foreign Application Priority Data
Sep. 17, 2015 (DE) 10 2015 115 749.7

(51) Int. Cl. H03K 17/96

(52) U.S. Cl. CPC H03K 17/962; H03K 2217/960765

(57) ABSTRACT

The invention relates to a capacitive sensor system comprising sensor electronics and a sensor portion (1) consisting of a synthetic construction material which comprises a sensor electrode (3; 22) and to a method for the production and use of said sensor system.

The invention relates to a capacitive sensor system comprising sensor electronics and a sensor portion, which can be primarily used in the building industry and to a method for the production and use of same.

GB 2 368 126 describes a capacitive sensor, which is inserted into a wall as a switch and, for example, is covered by a tile. WO 2015/104480 A1 discloses a switch, which is to be placed behind an opaque wall so that it cannot be recognized from an outer side, but can be operated from the outer side.

The object of the invention is to functionalize components and, above all, walls, supports and the like, in or on buildings without requiring movable devices that are therefore prone to wear and tear.

The task is solved by means of a capacitive sensor system with sensor electronics and by means of a sensor portion made of a synthetic construction material comprising a sensor electrode. The sensor electronics, which are themselves known, which can contain or contain a sensor chip or a signal converter and a power source for example, maintain a constant power flow to the sensor electrode to generate an electrostatic stray field, detect a change in potential of the stray field and convert it into a signal. An electronic component itself is a primary element of the invention, comprising at least a portion designed as a sensor, the sensor portion. According to the invention, the sensor portion is made of a synthetic construction material, into which a sensor electrode is embedded. The term synthetic construction material is to be understood as any construction material that is not naturally produced, but is artificial in the sense that it is composed of a plurality of different or identical components so that its new composition or structure can no longer be traced back to a natural origin. The most commonly used and, in this sense, synthetic construction material is concrete, which comprises natural source materials such as water and gravel as an aggregate, however, also requires synthetic materials such as cement and can ultimately be recognized as a synthetic construction material in its hardened form. In addition, the term synthetic construction materials is to be understood to mean such materials that are applied alone or in conjunction with concrete as its coating, such as all types of gypsums, plasters, screeds or plastics. In this respect, for the sensor portion, it does not necessarily have to be a homogeneous construction material, but it can also consist of a combination of inherently different construction materials combined into a single compact component. The construction material wood is also understood as a synthetic construction material in terms of the invention, to the extent it is not used in its natural form, but once it has been processed or modified in any way. For example, this includes laminated timber beams, chipboards, wooden composite boards and wooden components with veneers. Gypsum plasterboards, mineral materials and fibre-reinforced composites and their possible combination are possible. Furthermore, all of these construction materials have in common that their treatment or their processing takes place at temperatures of up to 100° C., 150° C. or a maximum of 200° C., which do not harm electronics, and they themselves can be largely opaque, therefore being able to be functionalized in a concealed manner.

The capacitive sensor system according to the invention therefore works on the basis of the capacitance change of a single capacitor or a capacitor system, the electrode of which, referred to in the present document as sensor electrode, is an element of the sensor system, whereas the other electrode, to this extent, is a non-related moving body, for example, a users hand. According to the invention, the sensor electrode is surrounded by the synthetic construction material. This is to be understood to mean that the sensor electrode is not, for example, surrounded by a housing, which is connected to the construction material or attached to a component made of the synthetic material. Instead, the synthetic material and the housing-free sensor electrode according to the invention are in direct, regular, and inextricably-linked contact with each other. This construction makes it possible to arrange the sensor electrode extremely near the surface, thereby still largely remaining invisible, or on the surface. The proximity to the surface promotes the capacitive sensor system's operation, because it increases the precision of the sensor system's effect, thereby being able to reduce the energy required for its operation. Furthermore, the construction according to the invention also allows sensor electrodes to be almost any shape, in particular, cuboid or spherical, flat, rod-shaped, each being curved and, in addition, irregularly shaped sensor electrodes.

According to an advantageous embodiment of the invention, the sensor electrode can be fully embedded into the construction material. The embedded sensor electrode offers the advantage of being invisible within the opaque construction material so that a functionalization of the component manufactured from it cannot necessarily be detected. In doing so, the technology required for functionalization does not compromise the aesthetic impression the component makes. In addition, the embedding offers an effective protection against mechanical damage and environmental factors, such as weather conditions and the like, for the sensor electrode and its possible microelectronic components.

During operation, the sensor electrode generates an electrical field around itself, which changes when the sensor electrode is approached or touched. Depending on the geometrical shape of the sensor electrode, it generates an electric field with homogeneous and inhomogeneous areas. In particular, the homogeneous area generally sets the detection direction of the capacitive sensor system. According to another favourable embodiment of the invention, the sensor system can comprise a shield electrode surrounding the sensor electrode on at least one plane that is orthogonal to the detection direction. It is used to shield inhomogeneous peripheral areas of the electrical field of the sensor electrode. In this way, an approximately parallel electric field with a per se known characteristic of an ideal plate capacitor develops between the sensor electrode and the moving body to be detected. Thereby, even minor changes in the electrical field can be better detected, which increases the efficiency of the capacitive sensor system.

The shield electrode can also surround the sensor electrode multilaterally, in particular, on its rear side, in order to limit its detection direction to the “front side”. Overall, the shield electrode serves to define the stray field and the sensor electrode's detection range. The constructive design of the shield electrode is therefore largely based on the shape of the sensor electrode. That can, even without using a shield electrode, largely assume any spatial shape and is not limited to a cylindrical or planar shape. For a dome-shaped sensor electrode, the convex surface of which determines the detection range, a circular or disc-shaped shield electrode may be necessary, that possibly has a flared edge.

According to another favourable embodiment of the invention, in any case, the sensor electrodes and, if applicable, also the shield electrode, provided it is available, and other conductive sensor components can be electrically insulated. For example, they can additionally be surrounded with a plastic, paint or powder coating. The electrical insulation of the conductive sensor components of the surrounding construction materials prevents interference to the sensor system, provided that the material contains water or moisture is applied to it during operation.

According to another favourable embodiment of the invention, the concrete surrounding the sensor portion or the concrete matrix themselves can undertake the task of shielding or the field containment of the sensor electrodes, meaning the function of the shield electrode. At a low electrical conductivity of the concrete, it can also act like a shield electrode itself within the range of the sensor electrode due to its mass and power, thereby limiting the detection range of the sensor electrode or the sensor field. According to the invention the electrical conductivity of the concrete can be reduced by means of aggregates to the extent that the sensor field can be limited due to this. This is made possible, for example, by means of polymer aggregates. Provided that the processing temperatures can be maintained at under about 200° C., polymer concrete can also be used instead of normal concrete with polymer aggregates. In contrast to normal concrete, it contains a polymer or a plastic as a binder, which holds the rock particles or the aggregate together. In polymer concrete, cement is only used as a filler if at all, meaning as an expansion of the rock particles into the fine grain range and does not take on any binding effect. Thus, water, which is usually responsible for the binding effect in making cement paste, can be omitted as an element of the matrix and with it an important electrically conductive element in polymer concrete.

This embodiment of the invention is suitable for the arrangement of a plurality of sensor electrodes described further below. Their fields are shielded by the using polymer-modified concrete or polymer concrete, so that separate shield electrodes can be omitted. Via the position of the sensor system embedded within the polymer-modified or polymer matrix, additionally, the range of the detection field of a sensor electrode can be defined, meaning by positioning it within the edge area, near a component surface in a middle position or deeply sunken in, meaning removed from the surface. Meaning that ultimately different concretes for manufacturing the sensor portion can be combined, and a “non-conductive” polymer-modified or polymer concrete in order to limit the sensor field in a certain direction, and a “conductive” normal concrete apart from that.

According to another favourable embodiment of the invention, the sensor system can comprise positioning means, which are coupled with the sensor electrode and, where applicable, with the shield electrode, thereby defining their position in the sensor portion. The positioning means serve in any case to configure the position of the sensor electrode, however, if applicable, also the shield electrode in the future component in a highly precise manner, above all, with regard to its distance to the surface of the component in the detection direction. In order not to otherwise influence the effect of the sensor system, in particular, non-conductive materials are suitable for positioning means. Thereby, for example, this can be attachment means, with which the electrodes are attached to a reinforcement of a concrete component to be produced. As an alternative, a positioning frame can hold the sensor electrode and, if applicable, the shield electrode, and affix it within a formwork device for a concrete component in order to define the position of the electrode during the introduction of the concrete, during compression and subsequent hardening. Like a permanent formwork, the positioning means can either remain within the hardened component or be removed at an appropriate time and be used for another manufacturing process.

According to another favourable embodiment of the invention, the shield electrodes can be designed as a means of positioning at the same time. This combination of functions allows lower level of material usage and assembly work. In addition to an insulation, the shield electrodes can also be equipped with an attachment means to the formwork device for a concrete component or to the casting mould for a plastic component, which will later serve as contacts for the earthing if applicable.

According to another favourable embodiment of the invention, the sensor system can have a plurality of sensor electrodes with abutting or at least partially overlapping stray fields or detection ranges. Shield electrodes can result in the reduction or avoidance of overlaps. Furthermore, they can define functional surfaces on the future surface of the component, which are limited from each other and, if applicable, spaced away from each other.

According to another favourable embodiment of the invention, a plurality of sensor electrodes and, if applicable, corresponding shield electrodes can be arranged at the same level next to each other and form a control panel on a component surface. The arrangement next to each other also includes such an arrangement on top of each other. The term “the same level” is to be understood as the constructional level of the sensor electrodes, wherein not only level, but also curved or otherwise profiled surfaces, if applicable, are possible. With the arrangement of a plurality of sensor electrodes next to each other, separated functional surfaces can be formed, such as switch surfaces. On the contrary, interrelated functional surfaces allow for the implementation of dimming or sequential switching functions by means of gesture control such as wiping or touching gestures, or the like.

According to another favourable embodiment of the invention, the sensor system can be equipped with a reinforced sensor portion, wherein the reinforcement of the sensor portion has an electrical contacting so that the reinforcement forms a sensor electrode. In any case, a reinforcement of concrete is regularly made of electrically conductive material, namely out of so-called concrete steel. As an alternative, the reinforcement can be made of other metals or out of carbon fibres or carbon-based materials. Thereby, the reinforcement according to the invention can be used as a sensor electrode if it is electrically contacted and linked to sensor electronics mentioned in the above into a sensor system. With the double function as a reinforcement on the one hand, and a sensor electrode on the other, not only material and construction effort can be saved, but a possible electrical disturbance of a conventional reinforcement can also be ruled out. The (signal) power required to generate the electrical field, meaning the sensor field, can preferably be introduced into the reinforcement at an edge area of the sensor portion or of the reinforcement. The reinforcement can be contacted “as a whole”. An electrical contact point for the introduction of power, which can also function as a signal pickup unit at the same time, means that a homogenous sensor field is formed via the reinforcement and can be used for detection. The sensor field is generated according to the structure or arrangement of reinforcement. In this way, the reinforcement can have a linear design as a strand or as parallel strands or flat, for example, as a conventional concrete steel mesh, thereby generating sensor fields according to this.

According to another favourable embodiment of the invention, the reinforcement can be subdivided into subsections on an electrical level. In addition, a plurality of reinforcement sections can be formed or the reinforcement can be subdivided by insulators on a mere electrical level for example. Individual or a plurality of sensor fields and ranges can be defined via the number of signal power introduction points into the reinforcement sections and their electrical insulation and differentiation in subsections. Reinforcement elements and areas can be easily electrically insulated from each other and contacted individually so that a plurality of sensor fields form within a component and can be used in a complex way for detection. Thereby, for example, the detection of wiping gestures or the movement of objects on the component surface can be made possible and, furthermore, detection section by section or area by area of component statuses and weather influences etc.

According to another favourable embodiment of the invention, the sensor portion can have a flat reinforcement with reinforcement strands running in various directions and at an angle to each other, wherein parallel reinforcement strands are electrically insulated from the reinforcement strands running at the angle to them. In the case of the conventional mesh reinforcement made of concrete steel, the strands or the droves of parallel strands run at a right angle to one another, meaning, for example in the x-direction or in the y-direction running orthogonally to it. Both with concrete steel, as well as with other reinforcement materials such as carbon fibres however, droves of parallel strands at other than a 90° angle and, if applicable, more than only two running at an angle to each other can be formed. According to the invention, fibre strands of concrete steel meshes or carbon fibre meshes can be insulated at the cross points so that the sensor fields are formed along a fibre strand respectively. Concrete specially reinforced with carbon fibre meshes belongs to the field of textile concrete or textile-reinforced concrete (TRC). If a concrete steel mesh or an “commercially available” carbon fibre mesh is contacted as a reinforcement in the concrete, a homogenous sensor field is formed by the entire mesh because the signal flow to the cross points of two fibre strands is passed on respectively and, in this way, and is ultimately in contact across all strands in the x- and y-direction. According to the invention, the strands are insulated from each other at the cross points, meaning, for example, wrapped around non-conductive material at short sections, wherein the insulation of a strand principally suffices respectively. The static behaviour of the mesh changed in this way does not change, meaning that the forces continue to be transferred to the cross points, among other things. From an electrical point of view, however, an arrangement of elongated rod-like sensor electrodes results. The fibre strands can now be contacted individually and used as a sensor electrode. In this way, ultimately, a maximum of all fibre strands of the reinforcement mesh in the y-direction can be used for a sensor arrangement. In the same way, the strands in the x- or in the y-direction can be used or different groups of fibre strands in a temporally alternating manner can be used, or a single fibre strand.

The various functions of such arrangements illustrate the example of a detectable manual wiping gesture. If, for example, all strands are used in an x-direction as sensor electrodes, wiping gestures in the y-direction can be detected well and detected very precisely on a temporal and spatial level because the wiping hand generally subsequently goes across a plurality of strands or all strands in the x-direction. On the contrary, wiping gestures in the x-direction parallel to the sensor electrodes can only be inaccurately detected and located.

According to another favourable embodiment of the invention, so-called knit spacer fabrics or knit spacer fabrics made of conductive material or yarn, meaning knitted fabrics, which have been expanded to the third dimension, can be electrically insulated and contacted as a reinforcement in the aforementioned way. Spacer knitted fabrics are at least jersey knitted fabric or knitted fabrics, textiles or fibre meshes with connection threads (pile yarns), which keep the surfaces at a distance. In the case of spacer knitted fabrics, for example, the x-fibres of an upper level and the y-fibres of an lower level can be insulated against one another and respectively contacted, thereby being able to be used as a sensor electrode. The distance of the levels alone offer the advantage that a better insulation between the levels serving as sensor electrodes is ensured, whereby, for example, the signal power strength can be increased.

Depending on the application, the previously described sensor and shield electrodes can be omitted. Furthermore, combinations of conductive reinforcement and (additional) sensor and shield electrodes are also conceivable. The sensor field generated by means of the conductive reinforcement can also be limited by means of non-conductive concrete or polymer concrete or comparable matrix materials.

The aforementioned task is furthermore solved by means of a method of manufacturing a capacitive sensor with a sensor electrode embedded in a synthetic construction material, which comprises the following steps:
a) positioning of the sensor electrode and/or a shield electrode along with all electrical connections within a formwork device or cast mould,
b) introduction of a synthetic construction material into a formwork device or casting mould,
c) allowing the construction material to dry and stripping the formwork or demoulding of the component made of the synthetic construction material,
(d) connecting the electrodes to an electronics control system.

According to the invention, the method of manufacturing the capacitive sensor system is incorporated into the manufacturing method of a component made of a synthetic construction material. According to this, the method differs depending on what construction material is used. In the following, the process is shown using the example of a component made of a synthetic construction material, whereby technical terms from this field are used even if the method can be similarly applied to comparable manufacturing methods, for example for ceramic components. According to this, in a first step, the sensor electrode and the shield electrode, where applicable, is positioned in a formwork device in such a way that, when subsequently introducing the concrete, it does not change its position, in particular, against the future surface of the component to be manufactured. In addition, the electrodes can be attached to a non-conductive reinforcement, for example, to a glass fibre mesh or, using non-conductive elements, to a conventional reinforcement. As an alternative to this, intrinsic positioning means can be used, to which the electrodes are attached and, for their part, are set in the formwork device. Manufacturing the electrodes, for example, on a positioning frame or on reinforcement meshes allows for economic manufacturing, even when manufacturing large and geometrically complex components. In particular, during their manufacture, it can be favourable to use positioning means which can be removed from the formwork device even before finishing the component, for example, before stripping the formwork of a concrete component, in order for them to be able to be re-used. After accurate positioning of the electrodes, the concrete may be inserted into the formwork device. Despite the burdens occurring on the electrodes in the process, they maintain their defined position, even when the concrete is subsequently compressed by means of vibrators.

Apart from this, a usual manufacturing process for concrete components takes place, namely allowing the concrete to harden and stripping the formwork from the component. While the component is thereby initially finished, the electrodes of the capacitive sensor system are subsequently connected to an electronics control system, which, if applicable, is connected for its part to a power source and an earthing, provided that the shield electrodes are not separately earthed. This last step might have to be performed if required only after installation of the component in its end position within a building.

The aforementioned task is furthermore solved by using a capacitive sensor with the sensor portion made of a construction material as a manually operable control device, which is described in the above in more detail. According to this, the capacitive sensor system can be connected to an actuator, which controls a component of a building technology. The term building technology can be understood to mean just about any electrically operated device in a private or commercially used building, whereby an illumination, ventilation or air-conditioning device, an audio or video system or the like can be understood. In this way, the capacitive sensor system connected to an actuator can replace a light switch or an air-conditioning system for example. This is because, when subjected to the supply of an already weak electrical power, the sensor electrode generates an electrical field at the component surface in such a way that it changes when it is approached or touched as a consequence. The field change is transmitted as a signal to the signal processing unit in the electronic control system and is passed on as a control command to the actuator. Thereby, an illumination means can be switched on and off by simply touching a component surface. By arranging a plurality of sensor electrodes or sensor systems next to each other control panels or switchboards can, in this way, be formed which can also offer dimming and sequential switching functions in addition to simple switching operations.

The system according to the invention offers the advantage of a low level of power consumption, because the sensor electrode can be attached very close to the surface. Despite their attachment to or in a sensor portion made of a conventional construction material, the invention offers highly precise positioning and manufacturing of the sensor electrode.

The principle of the invention will be further explained using a drawing for the sake of example. The figures show:

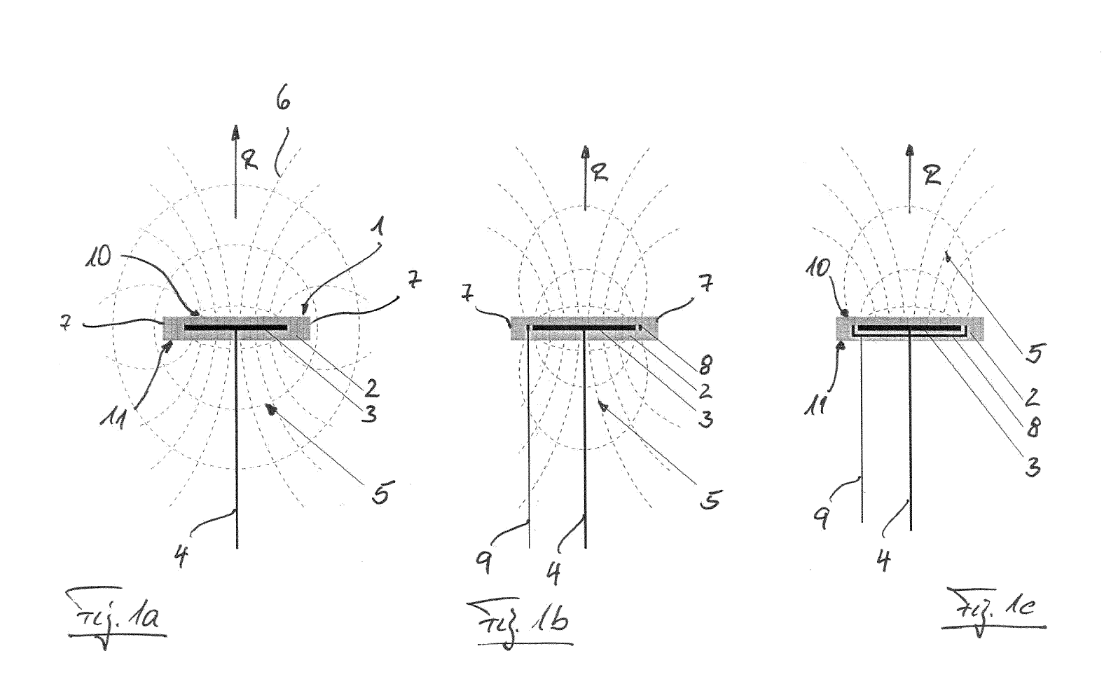

FIG. 1 a, b, c: Schematic representations for the construction of a sensor portion,

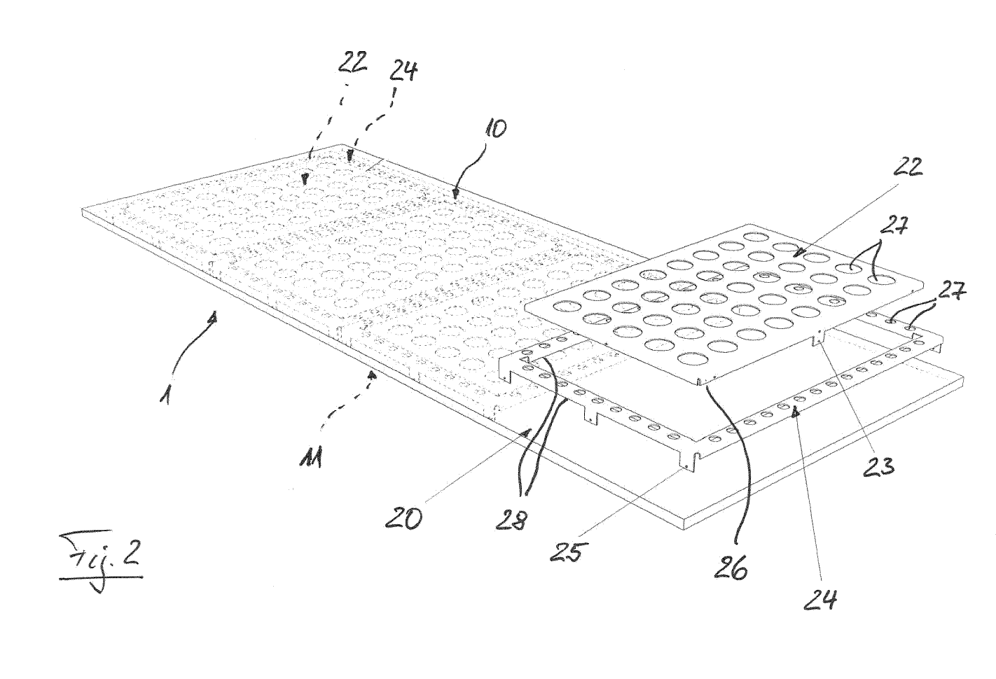

FIG. 2: a concrete element with a sensor and shield electrode in an exploded view, and

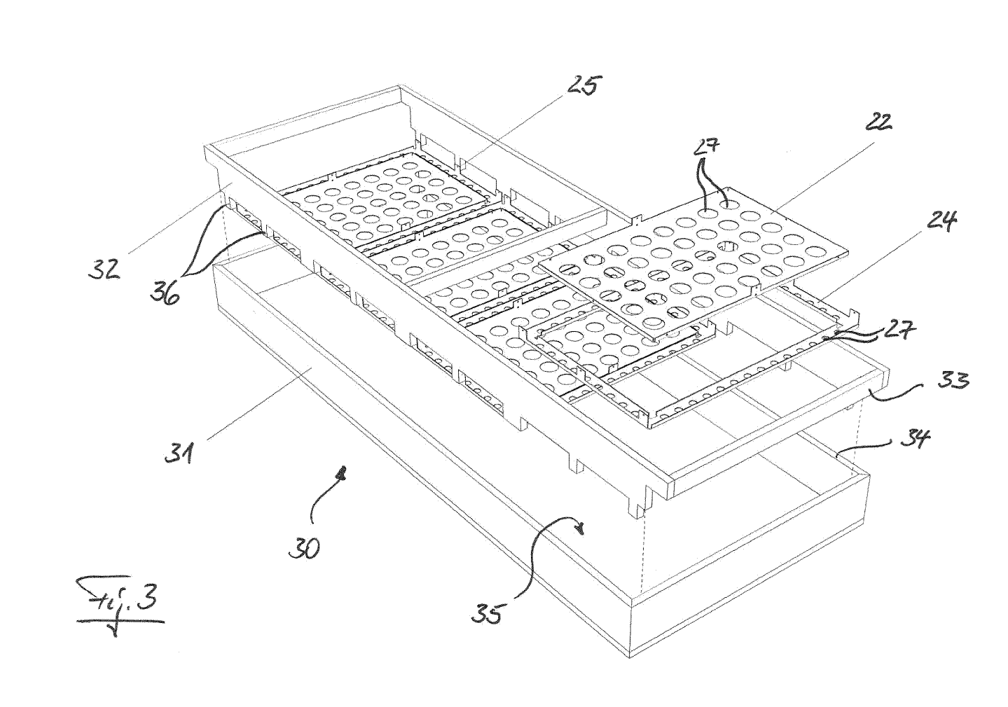

FIG. 3 tools for manufacturing the concrete element

FIG. 1a to 1c show sections of three sensor portions 1 of a capacitive sensor system in three basic forms. Altogether, FIG. 1a to 1c show a sensor section 1 made of a flat concrete block 2, in which a plate formed sensor electrode 3 is fully embedded. It is contacted with an electrode connection 4, which runs out of a concrete block 2 to a rear side 11 lying opposite to its upper side 10. The concrete block 2, which is also plate-shaped, has a thickness that corresponds to about three times the thickness of the sensor electrode 3. On its edge side, the concrete block 2 covers it by about three times its thickness. The concrete block 2 is, therefore, a relatively delicate component which encloses the sensor electrode 3 with thin walls and, in its outer shape, corresponds to the shape of the sensor electrode 3.

An electronics control system, not shown here, and a power source complement the sensor portion 1 shown into a capacitive sensor system. When applying a relatively weak current to the electrode connection 4, the sensor electrode 3 generates an electrostatic stray field 5, which represents the detection field of the sensor electrode 3. In a middle area of the sensor electrode 3, almost vertical field lines 6 are shown, which fall onto the edges 7 in an extremely inclined manner. The vertical field lines 6 define a detection direction R, which defines a direction of action of the capacitive sensor system. If a, generally speaking, earthed solid or fluid body gets into the stray field 5, it represents a second electrode of a capacitor in addition to the sensor electrode 3, the capacitance of which also changes along with the changing distance of the electrodes to each other. Upon approaching the sensor portion 1 against the detection direction R or upon touching the sensor portion 1, a change in voltage occurs which is captured by the electronic control system and is converted into a signal. A control command for an actuator can be generated from this, which opens or closes a switch.

FIG. 1a shows a sensor portion 1 with an unshielded sensor electrode 3. In contrast, according to FIG. 1b, in addition to the sensor electrode 3, the sensor portion 1 contains a shield electrode 8, which is attached around its circumference, thereby being attached to the narrow side edges of the plate-shaped sensor electrode 3. The shield electrode 8 has a grounding 9, which leads out of the sensor portion 1 as an insulated conductor. It serves to prevent the inhomogeneity of the field 5 at the edges 7 according to FIG. 1a and to limit the stray field 5 to approximately parallel field lines 6. Thereby, the sensitivity of the sensor portion 1 increases so that also smaller changes can be better detected and, at the same level of sensitivity of the sensor system, less power is required for this.

The stray field 5 of the sensor portion 1 forms at the upper side 10 in the rear side 11 in the same way. FIG. 1c shows a shield electrode 8 which surrounds the plate-shaped sensor electrode 3 on three sides in a sectional view, whereby the stray field 5 is concentrated on the upper side 10 of the sensor portion 3. It also has a grounding 9. Using the shield electrode 8 according to FIG. 1c, a further increase in efficiency of the sensor system can be achieved.

All known concrete mixtures can, in principle, be used for the concrete block 2. The sensor portion 1, made of the concrete block 2 and the sensor electrode 3 embedded within it, can be attached to the formwork of a concrete wall or its reinforcement or be integrated into brick masonry in the same way as a conventional installation component for example, such as a concrete flush-mounted socket for a switch or a lighting fixture. If the upper side 10 of the concrete block 2 coincides with the surface of the future building wall, the covering of the sensor electrode 3 against the upper side 10 defines the position of the sensor electrode 3 relative to the component surface. Thereby, the concrete block 2 can practically serve as positioning means, which defines the covering of the sensor electrode 3 and its relative position to a functional surface. It affects the spread and intensity of the stray field 5. However, the geometry of the sensor electrode 3, its size and the supplied electrical power can also define the expansion of the electrostatic stray field 5 generated by the sensor electrode 3, thereby defining the degree of touch sensitivity of the capacitive sensor system.

FIG. 2 shows an exploded view of the sensor portion 1 made of a plate-shaped concrete element 20 in which four rectangular plate-shaped sensor electrodes 22 and four shield electrodes 24 are embedded. The thickness of the concrete element 20 is only 20 mm, its length approximately 1 m and its width approximately 0.5 m. FIG. 2 offers a view of the upper side 10 of the sensor portion 1. The concrete element 20 encloses the four shield electrodes 24 arranged next to each other, which each surrounding a sensor electrode 22 in a frame-shaped manner. Each sensor electrode 22 consists of a metal sheet upturned at the edge, which has a variety of circular breakthroughs 27. In the installed state of the sensor electrode 22, they are filled with concrete and lead to a good interlocking between the sensor electrode 22 and the concrete element 20. Flap-shaped connections 23 of the sensor electrode 22 protrude at the upturns 26 located at the edge. Due to its length, they protrude from a rear side 11 of the concrete element 20, which is concealed in FIG. 2, so that they are not encapsulated with concrete when the sensor portion 1 is manufactured. In particular, each sensor electrode 22 is electrically insulated with relation to the shield electrode 24 as it is bears a plastic-powder coating.

The shield electrode 24 is principally constructed in a manner similar to the sensor electrode 22. It is also made of a bent sheet material the edge of upturns 28 of which provide for torsional stiffness of the frame-shaped shield electrode 24. The flap-shaped connections 25 protrude at the upturns 28, which protrude out of the future concrete element 20 like the connections 23 of the sensor electrode 22, thereby making an electrical contacting of the shield electrodes 24 possible. The shield electrode 24 also has a plastic-powder coating as an electrical insulation and is riddled with a plurality of circular breakthroughs 27.

FIG. 3 illustrates the manufacture of the concrete element 20 overhead in an appropriate formwork device 30. A formwork tub 31 determines the outer dimensions of the concrete element 20 according to length and width. A positioning frame 32 can be inserted into it, which is supported by means of edge brackets 33 on an edge 34 of the formwork tub 31 so that it does not touch a base surface 35 of the formwork tub 31. Thereby, it almost hangs into in the formwork tub 31. The shield electrodes 24 can be attached to their connections 25 at pins 36 protruding from it and protruding into the formwork tub 31. The sensor electrodes 22 are attached to the shield electrodes 25 via their connections 23 (not shown). Thereby the position frame 32 holds the sensor electrodes 22 and the shield electrodes 24 at a precisely defined distance over the base surface 35 of the formwork tub 31. Thereby, it defines an installation depth of the electrodes 22, 24 in the concrete element 20 as well as their distance from its surface 10 (FIGS. 1, 2).

After mounting the sensor electrodes 22 and the shield electrodes 24 in the positioning frame 32 and inserting it into the formwork tub 31, the concrete is introduced. Due to the numerous breakthroughs 27 in the electrodes 22, 24, a more viable connection between the electrodes 22, 24 results on the one hand, and between the future concrete element 20 on the other. At the same time, the electrodes 22, 24 act as a reinforcement for the concrete element 20. Only the connections 23, 25 of the electrodes 22, 24 protrude over a fresh concrete surface so that they and the positioning frame 32 remain untouched by the concrete. After the concrete reaches a sufficient level of stiffness, the positioning frame 32 can be removed and re-used for a subsequent manufacturing step. After full hardening of the concrete in the formwork tub 31, the concrete element 20 can be stripped from the formwork and is available for proper use as a sensor portion 1.

Since the preceding sensor portions 1 described in detail have to do with exemplary embodiments, they can usually be modified by a person skilled in the art to a further extent without going beyond the scope of the invention. In particular, the specific embodiments of the electrodes 22, 24 can also be formed in a different geometrical shape than what is described here. The sensor section 1 can also be made of other materials and also be designed with a different geometrical shape if this is required due to lack of space or for design reasons. Still, the use of the indefinite article “a” or “an” does not rule out that several relevant features can also be present a multiple of times or available several times.

### REFERENCE LIST

1 Sensor portion
2 Concrete block
3 Sensor electrode
4 Electrode connection
5 Stray field
6 Field lines
7 Pole
8 Shield electrode
9 Grounding
10 Upper side
11 Rear side
20 Concrete element
22 Sensor electrode
23 Connection
24 Electrode
25 Connection
26 Upturn
27 Breaks
28 Upturn
30 Formwork device/casting mould
31 Formwork tub
32 Positioning frame
33 Bracket
34 Edge
35 Floor surface
36 pin
R Detection direction

1. A capacitive sensor system comprising sensor electronics and a sensor portion including a synthetic construction material and a sensor electrode embedded into the synthetic construction material.

2. The capacitive sensor system according to claim 1 with a detection direction (R), characterized by a shield electrode surrounding the sensor electrode at least on a level which is orthogonal to the detection direction (R).

3. The capacitive sensor system according to claim 2, characterized in that the sensor electrode and/or the shield electrode is/are electrically insulated.

4. The capacitive sensor system according to claim 2, characterized by positioning means, which are coupled with the sensor and/or shield electrode(s) and define their position in the sensor portion.

5. The capacitive sensor system according to claim 1, the synthetic construction material characterized by polymer-modified concrete or polymer concrete.

6. The capacitive sensor system according to claim 1, characterized by a plurality of sensor electrodes with stray fields that overlap.

7. The capacitive sensor system according to claim 3, characterized by the arrangement of a plurality of sensor electrodes and the shield electrode on a same level next to each other to form a control panel on a component surface.

8. The capacitive sensor system according to claim 1 with a reinforced sensor portion and an electrical contacting of the reinforcement of the sensor portion.

9. The capacitive sensor system according to claim 8, characterized by an electrical subdivision of the reinforcement into subsections.

10. The capacitive sensor system according to claim 8, wherein the reinforcement is characterized by a flat reinforcement with reinforcement strands running in various directions and at an angle to each other, wherein parallel reinforcement strands are electrically insulated from the reinforcement strands running at the angle to them.

11. The capacitive sensor system according to claim 10, wherein the reinforcement is characterized by a mesh reinforcement made of carbon fibre meshes.

12. The capacitive sensor system according to claim 8, characterized by spacer knit fabric made of a conductive material as the reinforcement.

13. A method of manufacturing a capacitive sensor with a sensor electrode embedded into a synthetic construction material, with the following steps:
a) positioning of the sensor electrode and/or of a shield electrode within a formwork device/cast mold,
b) introduction of the synthetic construction material into the formwork device,
c) allowing the synthetic construction material to harden and stripping the formwork/demolding of the sensor electrode and/or the shield electrode,
d) connecting the sensor and/or shield electrodes to an electronics control system.

14. A use of a capacitive sensor with a sensor portion made of a synthetic construction material according to claim 1 as a manually operable control device, in particular for building technology.
